(19) United States
(12) Patent Application Publication
(10) Pub. No.: US 2013/0128470 A1
(43) Pub. Date: May 23, 2013

(54) Backlight Module, Backplane and LCD Device

(71) Applicants: Yicheng Kuo, Shenzhen (CN); Yuchun Hsiao, Shenzhen (CN); Chong Huang, Shenzhen (CN); Jiahe Cheng, Shenzhen (CN); Chengwen Que, Shenzhen (CN); Quan Li, Shenzhen (CN); Liuyang Yang, Shenzhen (CN)

(72) Inventors: Yicheng Kuo, Shenzhen (CN); Yuchun Hsiao, Shenzhen (CN); Chong Huang, Shenzhen (CN); Jiahe Cheng, Shenzhen (CN); Chengwen Que, Shenzhen (CN); Quan Li, Shenzhen (CN); Liuyang Yang, Shenzhen (CN)

(21) Appl. No.: 13/375,909

(22) PCT Filed: Dec. 1, 2011
(86) PCT No.: PCT/CN2011/083289

§ 371 Date: Mar. 1, 2012

(30) Foreign Application Priority Data
Nov. 18, 2011 (CN) 2011103695723

(51) Int. Cl. H05K 7/00

(52) U.S. Cl. 361/748

(57) ABSTRACT

The present invention discloses a backlight module, a backplane and an LCD device. The backlight module comprises a backplane, a PCB and locking pieces for fixing the PCB on the backplane; the backplane surface is provided with multiple through holes, and the locking pieces are selectively arranged in the through holes. In the present invention, because the backplane surface is provided with through holes for arranging hillocks, the hillocks are arranged in the through holes in random positions. Thus, the hillocks are arranged in the through holes in the corresponding positions in accordance with the PCB size, so that the backplane can be adapted for PCBs of different size, and its generality can be increased. In addition, hillocks and through holes of corresponding number can be arranged in accordance with the number of different components. Thus, the backplane has higher generality, and then the production cost and the processing cost of the backplane can be reduced.

### TECHNICAL FIELD

The present invention relates to the field of liquid crystal displays (LCDs), and more particularly to a backlight module, a backplane and an LCD device.

### BACKGROUND

As a device for providing a light source in an LCD device, a backlight module comprises a backplane, a light guide plate, an optical diaphragm, Light Emitting Diode (LED) light bar(s) and the like; most components are locked and fixed on the backplane, for example, a printed circuit board (PBC) is locked on the backplane by hillock(s).

Hillock is a structure which is arranged on the backplane and is used for fixing the PCB and the like. In general, the hillock protrudes the backplane surface, and the PCB is fixed on the hillock by screws or other locking pieces, and then the short circuit caused by direct contact between the PCB and the backplane surface is avoided. An existing backplane is as shown in FIG. 1, and the hillocks 80 on the backplane are integrally stamped and formed on the backplane when the backplane is made. Thus, the positions of the hillocks 80 on the backplane are fixed so that it is difficult to adapt for the PCBs of different size; meanwhile, for the backlight modules requiring PCBs of different size and components of different number, corresponding backplanes are required to be mold-made; and for PCBs of different size, new backplanes are required to be mold-made. Thus, the generality of backplanes is poor, and the production cost is high under the condition.

### SUMMARY

The aim of the present invention is to provide a backlight module with good generality, a backplane and an LCD device.

The purpose of the present invention is achieved by the following technical schemes. A backlight module comprises a backplane, a PCB and locking pieces for fixing the PCB on the backplane; the backplane surface is provided with multiple through holes, and the locking pieces are selectively arranged in the through holes.

Preferably, the locking pieces can be arranged in the corresponding through holes of the backplane in accordance with the PCB size. By determining the PCB size, the locking pieces are arranged in the corresponding through holes. Thus, PCBs of different size can be arranged by the backplanes of the same size.

Preferably, the through holes in said backplane surface are a series of standard holes, and said locking pieces are selectively fixed in said standard holes. A series of standard holes are easily machined, and are adapted for PCBs of different size.

Preferably, the through holes in said backplane surface are multiple holes arranged correspondingly in accordance with PCBs of different size, and the locking pieces are selectively fixed in the multiple holes. Because multiple holes are correspondingly arranged in accordance with the PCB size of various specifications, one backplane is adapted for PCBs of various size, and some unnecessary holes are avoided, so that the strength of the backplane is not weakened.

Preferably, each locking piece is a hillock, and the bottom of the hillock is provided with a fixed structure for arranging the hillock in the through hole. The hillock has good effect for locking PCB, and avoids the short circuit of PCB circuits.

Preferably, the fixed structure is a threaded hole arranged at the bottom of the hillock. The hillock can be conveniently arranged on the backplane by screw(s), and can be removed.

Preferably, the threaded hole penetrates through the hillock. Thus, the PCB, the hillock and the backplane can be mutually fixed by only one screw, and the three components are fixed because the screw passes through the PCB, the hillock and the backplane and is locked by a nut.

Preferably, the fixed structure is a rivet integrally arranged at the bottom of the hillock. The riveting mode has the advantages of simplicity, convenience, quickness and high reliability, and can be accomplished by machinery.

Preferably, each locking piece is an independent mushroom head. The mode for locking PCB by the mushroom head is convenient and quick.

A backplane, the backplane surface is provided with through holes for arranging locking pieces.

Preferably, the through holes in the backplane surface are a series of standard holes. A series of standard holes are easily machined, and are adapted for PCBs of different size.

Preferably, the through holes in the backplane surface are multiple holes arranged in accordance with PCBs of various specifications. Because multiple holes are correspondingly arranged in accordance with the PCB size of various specifications, one backplane is adapted for PCBs of various size, and some unnecessary holes are avoided, so that the strength of the backplane is not weakened.

An LCD device comprises any one of the aforementioned backlight modules.

In the present invention, because the backplane surface is provided with multiple through holes for arranging the hillocks, the hillocks are arranged in the random through holes. Thus, the hillocks are arranged in the corresponding through holes in accordance with the PCB size, so that the backplane can be adapted for PCBs of different size, and its generality can be increased. In addition, hillocks and through holes of corresponding number can be arranged in accordance with the number of different components. Thus, the backplane has higher generality, and then the production cost and the processing cost of the backplane can be reduced.

### BRIEF DESCRIPTION OF FIGURES

FIG. 1 is a simplified structure diagram of an existing backplane;

FIG. 2 is a simplified structure diagram of a backplane of an example of the present invention;

FIG. 3 is a simplified structure diagram of one hillock of an example of the present invention;

FIG. 4 is a structure diagram of a PCB locked by one hillock of an example of the present invention;

FIG. 5 is a simplified structure diagram of the other hillock of an example of the present invention;

FIG. 6 is a structure diagram of a PCB locked by the other hillock of an example of the present invention; and

FIG. 7 is a simplified structure diagram of a third hillock of an example of the present invention.

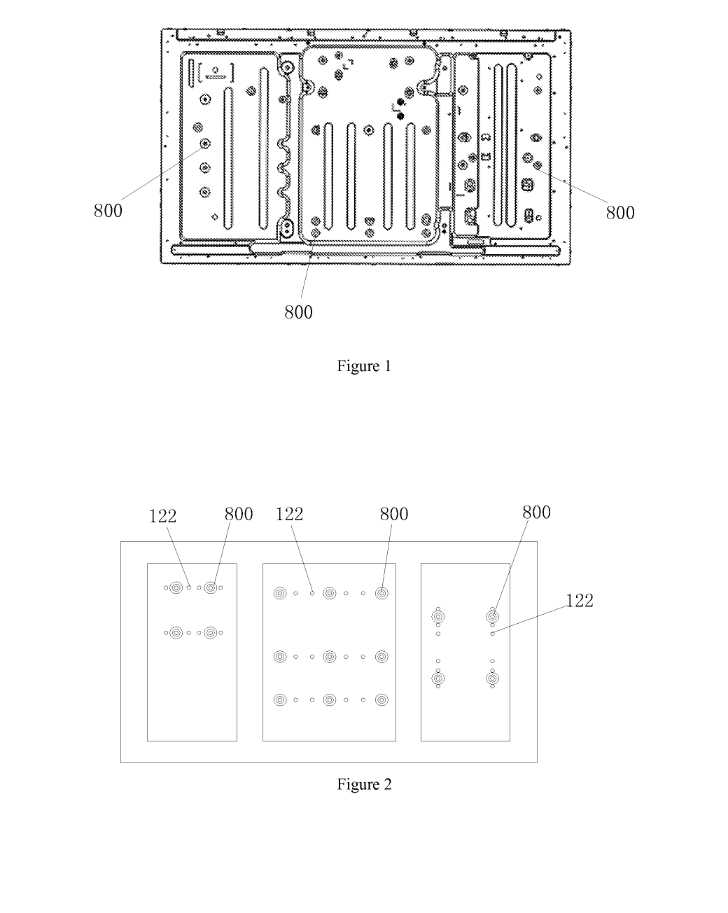

Wherein: 1. backplane; 122. through hole; 800. hillock; 810. threaded hole; 811. screw; 812. nut; 820. rivet; 300. PCB.

### DETAILED DESCRIPTION

The present invention provides an LCD device. The LCD device comprises an LCD panel and a backlight module. The bottom of the backlight module is provided with a backplane, wherein the backplane surface is provided with multiple holes for arranging hillocks. In accordance with the scheme, the invention will further be described in detail in accordance with the following preferred examples.

In the backlight module, most components are arranged and fixed on the backplane, for example, the PCB is fixed on the backplane by the hillocks on the backplane, and the backplane is made by processing one integral panel, or multiple panels or multiple panels of different material.

FIG. 2 shows a backplane formed by processing an integral panel. The backplane surface is provided with through holes 122, the through holes 122 are arranged in the corresponding positions of the backplane surface in accordance with the size of frequently-used PCBs or other components. Namely, for the PCB of each specification, the backplane surface is provided with multiple corresponding through holes 122, and hillocks 800 are selectively fixed in the multiple through holes 122 as required. Because multiple holes are correspondingly arranged in accordance with the PCB size of various specifications, one backplane is adapted for PCBs of various size, and some unnecessary holes are avoided, so that the strength of the backplane is not weakened; alternatively, the backplane surface is provided with a series of equispaced standard holes, the standard holes cover the through holes 122 required by PCBs of various specifications so as to facilitate processing, and the hillocks 800 are selectively fixed in the standard holes in accordance with the PCB size. Each hillock 800 as an independent existing part is arranged in a through hole 122. The hillocks 800 are arranged in the corresponding through holes 122 in accordance with the PCBs of various size and specifications. Thus, the PCB of the size is locked on the backplane.

Of course, the PCB can be locked on the backplane by other similar locking pieces such as mushroom heads and the like besides hillocks. The mushroom heads are made into independent existing parts and are arranged in the through holes as the hillocks, and the PCBs of different size are locked in the same way.

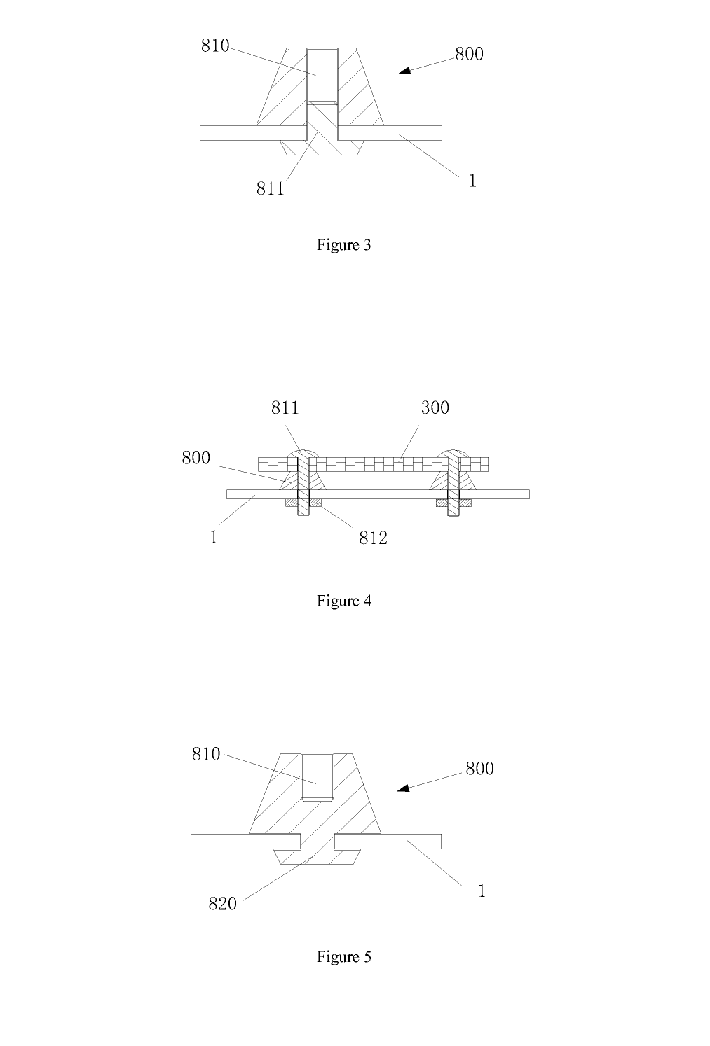

FIG. 3 and FIG. 5 show a hillock 800 existing as an independent part in the example. The hillocks of the type are not formed on the backplane when the backplane is manufactured, but the hillocks 800 are arranged in the corresponding through holes of the backplane 1 to achieve the aim of positioning PCB and the like of different size by flexibly using the hillocks 800.

As shown in FIG. 3, the hillock 800 has a threaded hole 810 for arranging and fixing the PCB and the like, and the threaded hole 810 penetrates through the independent hillock 800. Thus, the independent hillock 800 can be fixed on the backplane 1 from the lower part through a screw 811, and can fix the PCB from the upper part. Accordingly, the backplane 1 is provided with hillock mounting holes, such as through holes or chutes, of which the size is corresponding to that of the threaded hole 810 of each hillock 800, so that the hillock 800 can be fixed on the backplane. Similarly, the PCB, the hillock and the backplane are fixed by using one screw matching with a nut. As shown in FIG. 4, because the threaded hole penetrates through the whole hillock 800, the PCB 300 is directly locked on the backplane 1 by a screw 811 matching with a nut 812.

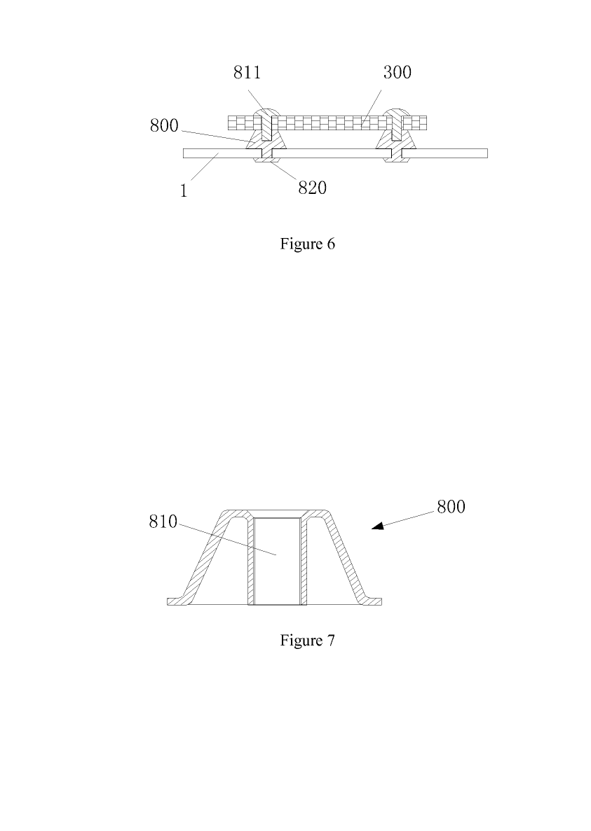

In order to facilitate installation, as shown in FIG. 5, the bottom of the hillock is designed into a structure similar to a rivet, namely the rivet and the hillock are integrally formed. The lower end of the hillock 800 is connected with the backplane 1 by riveting, namely the hillock 800 is riveted on the backplane 1 by a rivet 820. The riveting mode is relative to the screwing mode, can be quickly achieved, and can be accomplished by machinery so that the production efficiency can be increased. As shown in FIG. 6, the hillock 800 is fixed on the backplane 1 by the rivet 820, and then the PCB 300 is fixed on the hillock by the screw 811 so that the PCB 300 is locked.

To save material and facilitate processing, the hillock can be formed by directly stamping a panel, as shown in FIG. 7, the inside of the hillock 800 is of a hollow structure, and the whole hillock 800 is made of panel material.

Of course, the shape of the independent hillock 800 in the example is not limited to the conical section shape shown in the figure, other shape such as square can achieve the corresponding use.

In the example, corresponding hillocks are arranged in corresponding positions in accordance with the PCB size of the backlight module; meanwhile, corresponding hillocks are arranged in accordance with the number of different PCB components.

The present invention is described in detail in accordance with the above contents with the specific preferred examples. However, this invention is not limited to the specific examples. For the ordinary technical personnel of the technical field of the present invention, on the premise of keeping the conception of the present invention, the technical personnel can also make simple deductions or replacements, and all of which should be considered to belong to the protection scope of the present invention.

We claim:

1. A backlight module, comprising: a backplane, a PCB and locking pieces for fixing the PCB on the backplane; said backplane surface is provided with multiple through holes, and said locking pieces are selectively arranged in the through holes.

2. The backlight module of claim 1, wherein said locking pieces can be arranged in the corresponding through holes of the backplane in accordance with the PCB size.

3. The backlight module of claim 2, wherein the through holes in said backplane surface are a series of standard holes, and said locking pieces are selectively fixed in said standard holes.

4. The backlight module of claim 2, wherein the through holes in said backplane surface are multiple holes correspondingly arranged in accordance with PCBs of various specifications, and said locking pieces are selectively fixed in said multiple holes.

5. The backlight module of claim 2, wherein each said locking piece is a hillock, and the bottom of said hillock is provided with a fixed structure for arranging the hillock in said through hole.

6. The backlight module of claim 5, wherein said fixed structure is a threaded hole arranged at the bottom of the hillock.

7. The backlight module of claim 6, wherein said threaded hole penetrates through the hillock.

8. The backlight module of claim 2, wherein said fixed structure is a rivet integrally arranged at the bottom of the hillock.

9. The backlight module of claim 2, wherein said locking piece is an independent mushroom head.

10. A backplane, said backplane surface is provided with through holes for arranging the locking pieces.

11. The backplane of claim 10, wherein the through holes in said backplane surface are a series of standard holes.

12. The backplane of claim 10, wherein the through holes in said backplane surface are multiple holes correspondingly arranged in accordance with PCBs of various specifications.

13. An CD device, comprising: the backlight module of claim 1. Said backlight module comprises a backplane, a PCB and locking pieces for fixing the PCB on the backplane; said backplane surface is provided with multiple through holes, and said locking pieces are selectively arranged in the through holes.

14. The LCD device of claim 13, said locking pieces can be arranged in the corresponding through holes in the backplane in accordance with the PCB size.

15. The LCD device of claim 14, wherein the through holes in said backplane surface are a series of standard holes, and said locking pieces are selectively fixed in said standard holes.

16. The LCD device of claim 14, wherein the through holes in said backplane surface are multiple holes correspondingly arranged in accordance with PCBs of various specifications, and said locking pieces are selectively fixed in said multiple holes.

17. The LCD device of claim 14, wherein each said locking piece is a hillock, and the bottom of said hillock is provided with a fixed structure for arranging the hillock in said through hole.

18. The LCD device of claim 17, wherein said fixed structure is a threaded hole arranged at the bottom of the hillock.

19. The LCD device of claim 18, wherein said threaded hole penetrates through the hillock.

20. The LCD device of claim 14, wherein said fixed structure is a rivet integrally arranged at the bottom of the hillock.

21. The LCD device of claim 14, wherein said locking piece is an independent mushroom head.
